(19) United States
(12) Patent Application Publication
(10) Pub. No.: US 2009/0056794 A1
(43) Pub. Date: Mar. 5, 2009

(54) OPERATING DEVICES INCLUDING EMBEDDED NANOPARTICLES

(75) Inventors: Lin Shao, College Station, TX (US); Mark Hollander, Los Alamos, NM (US)

Correspondence Address: FISH & RICHARDSON P.C., P.O. BOX 1022, MINNEAPOLIS, MN, 55440-1022, US

(73) Assignee: TEXAS A&M UNIVERSITY SYSTEM, THE, College Station, TX (US)

(21) Appl. No.: 11/951,962

(22) Filed: Dec. 6, 2007

Related U.S. Application Data
(60) Provisional application No. 60/969,532, filed on Aug. 31, 2007.

(51) Int. Cl. H01L 31/00

(52) U.S. Cl. 136/252

(57) ABSTRACT

The present disclosure is directed to a system and method for operating a device including embedded nanoparticles. In some implementations, the method includes selectively illuminating at least a portion of a device including material having embedded nanoparticles. The nanoparticles emit electrons in response to light at a certain frequency or above. At least one operating parameter of the device is adjusted to direct at least a portion of the emitted electrons.

### CLAIM OF PRIORITY

This application claims priority under 35 USC §119(e) to U.S. Patent Application Ser. No. 60/969,532, filed on Aug. 31, 2007, the entire contents of which are hereby incorporated by reference.

### TECHNICAL FIELD

The present invention relates generally to optical detector and optoelectronics and, more particularly, to operating devices including embedded nanoparticles.

### BACKGROUND

The photoelectric effect is a quantum electronic phenomenon in which electrons are emitted from matter after the absorption of energy from electromagnetic radiation such as x-rays. This effect has been used to develop various devices such as photomultiplier, phototransistor, and photodiode. When optics are integrated with microelectronics, optoelectronics can be formed. Typical applications of optoelectronics include opto-electronic actuators, opto-electronic detectors and opto-electronic modulators and amplifiers, and transverse electromagnetic wave and optical circuits.

Driven by the need to further improve device performance, efficiency of room temperature photoemission needs to be increased. This has been limited by the photoemissive materials used in previous devices. From the principle of photoelectric effect, photon-excited electrons have a limited diffusion length in photoemissive materials. Photoemission requires excited electrons be able to reach the surface with certain energy. Only those electrons near the surface typically can escape and contribute to electronic signals.

The integrability of opto-electronics into ultra large scale integrated circuits includes a number of technical issues. First, devices need to be integrable with silicon which has been widely used as substrates for integrated circuits. Second, the device volume needs to be significantly reduced. Many state of the art opto-electronics are relatively large and are usually of the order of several hundred cubic centimeters in volume.

Opto-electronics can be incorporated into a transistor structure to fabricate the basic computational unit. A transistor is a three-terminal semiconductor-based electrical device found in a wide variety of technologies, ranging from hand-held radios to very complex computing systems. Typically used as amplification or switching elements, transistors are fundamental to the design of electronic circuits. Many types of transistors have been developed; some examples are the pervasive metal-oxide-semiconductor field-effect-transistor (MOSFET), the bipolar junction transistor (BJT) and the thin film transistors (TFT). Transistors are commonly fabricated on sub-micrometer length scales, allowing very small, light-weight electronics-based technologies.

### SUMMARY

The present disclosure includes a method for fabricating structures containing high efficient photoemissive materials. The method includes forming self assembled nanovoids in substrate and forming metal nanoparticles at the void formed region due to metal-void decoration. The photoemissive materials are integrated with microelectronic devices to form optoelectronic devices.

The present disclosure is directed to a system and method for operating a device including embedded nanoparticles. In some implementations, the method includes selectively illuminating at least a portion of a device including material having embedded nanoparticles. The nanoparticles emit electrons in response to light at a certain frequency or above. At least one operating parameter of the device is adjusted to direct at least a portion of the emitted electrons.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is an illustration of an example system 100 for controlling electron density in a material;

FIG. 2A-E is a series of diagrams illustrating steps of an example process for fabricating particles embedded in material;

FIG. 3 is a flowchart illustrating an example method for fabricating a device as illustrated in FIG. 2;

FIG. 4 is a diagram illustrating an example implementation of the system 100;

FIG. 5 is a flowchart illustrating an example method for operating the system 400 of FIG. 4.

FIG. 6 is a diagram illustrating an example implementation of the system 100; and

FIG. 7 is a flowchart illustrating an example method for operating the system 600 of FIG. 6.

Like reference symbols in the various drawings indicate like elements.

### DETAILED DESCRIPTION

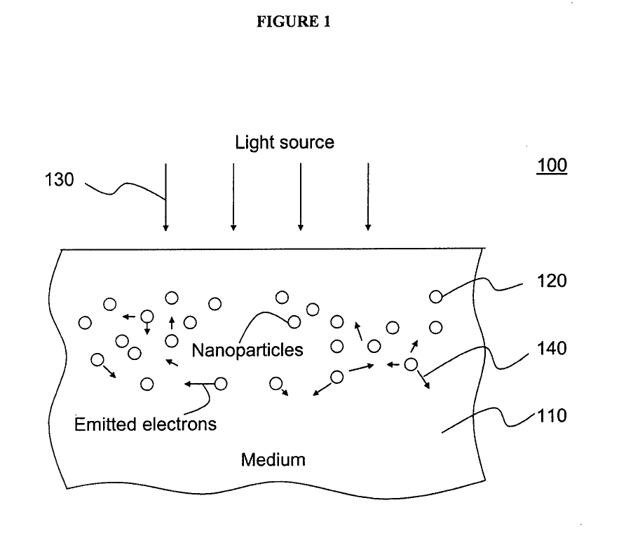

FIG. 1 is an illustration of an example system 100 for embedding photoemissive nanoparticles in materials in accordance with some implementations of the present disclosure. For example, the system 100 may dynamically modify the electron density of a material by illuminating embedded photoemissive nanoparticles. Nanoparticles may include structures with at least one dimension on the nanometer scale (e.g., 1-10 nm) formed from one or more metallic materials that emit electrons in response to at least photons above a certain frequency. As is known in the art, an energy (E) of a photon can be determined by E=hν, where h is Planck's constant in units of Joule seconds (J·s) and ν is the photon frequency in units of Hertz (Hz). When the energy of photons E exceeds at least the work function Φ_{w} of the nanoparticles, the nanoparticles can emit electrons. The electron yield, in units of number of electrons emitted into surrounding material per incident photon, may depend at least in part on the geometry, physical characteristics of the nanoparticles, and/or a type of surrounding material. In some implementations, the electron yield may be increased by designing the nanoparticles to have a diameter smaller than the diffusion length of excited electrons.

By embedding photoemissive nanoparticles in a material, the system 100 may dynamically modify the electron density in surrounding material by selectively switching an illumination source. In doing so, the system 100 can, in some implementations, modify one or more properties of the surrounding material such as electrical properties (e.g., conductivity) and/or optical properties (e.g., refractive index). In some implementations, the system 100 can be useful in a variety of applications such as optoelectronic systems and/or for optical modulation of materials. Optoelectronic systems may include devices such as optoelectronic actuators, optoelectronic detectors, optoelectronic modulators and amplifiers, and transverse electromagnetic wave and optical circuits. In an optical modulation application, the system 100 may dynamically modify, for example, the refractive index of the surrounding material such as in, for example, a silicon-based photonic circuit. In the case that the surrounding material is a monocrystalline silicon substrate, the system 100 may produce the embedded material may be integrated into very large scale integrated circuits because the nanoparticles are on the nanometer scale. In some implementations, the system 100 may be useful in optical detection and/or imaging applications.

At a high level, the system 100 includes material 110, the nanoparticles 120 and the light source 130. The nanoparticles 120 are embedded in the material 110 and illuminated by photons from the light source 130. If the incident photons have sufficient energy, electrons 140 may be emitted from the nanoparticles 120 into the surrounding material 110, which can modify the electron density of the material 110. The system 100 may include some, all, different, or additional features without departing from the scope of the present disclosure.

Turning to a detailed description of the elements, the material 110 can be any suitable material configured to transmit electrons and/or light. For example, the material 110 may be a semiconductor configured to transmit electrons in response to an applied voltage. In some implementations, the material may include one or more of the following: silicon (Si), silicon germanium, and/or other materials. The material 110 may be integrated in a portion of a device such as a transistor and/or optoelectronic device. At least a portion of the material 110 is configured to transmit photons to the embedded nanoparticles 120.

The nanoparticles 120 can be any material on the nanometer scale configured to emit electrons in response to photons above a certain frequency. For example, the nanoparticles 120 may comprise one or more metals (e.g., Au, Si, Cu). As previously mentioned, in some implementations, the nanoparticles 120 may have a diameter smaller than the diffusion length of the electrons excited by incident photons. For example, in some implementations, the nanoparticles 120 may be substantially spherical with a diameter ranging from 1 to 30 nm (e.g. 5 nm, 10 nm, 20 nm). The nanoparticles 120 may be embedded with a certain density in the material 110. In some implementations, density may be determined as a percentage of the volume of the material 110 occupied by the nanoparticles 120. A wide range of particle densities may be used (e.g., 10%). The particles may be embedded at a certain depth below the surface of the material 110, evenly distributed, or distributed in accordance with other patterns (e.g., Gaussian). In some implementations, the density, depth, and/or size of the nanoparticles 120 may be parameterized to allow a desired electron yield in a certain set of operating conditions. In some implementations, such as in optoelectronic applications, the nanoparticles 120 can be embedded near the surface of the material 110 at a depth of 1 μm or less. In other implementations, such as in optical modulation applications, the nanoparticles 120 may be embedded deeper than 1 μm and/or in multiple layers, at multiple depths, forming a sandwich-like structure.

The light source 130 may emit photons having an energy E greater than at least the work function Φ_{w} of the material of the nanoparticles 120. The light source 130 may emit light, for example, in the infrared or visible spectra. The light source 130 may generate light using any source geometry, such as a point source, a linear source, and/or a large-area source. Light emitted from the light source 130 may be incident on the nanoparticles 120 at any fixed angle or at multiple angles. The emitted light may have one or more of the following properties: narrow-band, wide-band, coherent, incoherent, polarized and/or non-polarized light. In addition, the properties may be varied over time. For example, the light source intensity, energy, flux, and/or others may be varied over time.

In one aspect of operation, the system 100 may be used to modify the electron density in the surrounding material 110. When off, the light source 130 is not emitting photons or the frequency of the emitted light is below a certain frequency such that electrons are not emitted by the nanoparticles 120. Under this condition, the electron density may have a base value determined by properties of the material 110. When the light source 130 is turned on, at least a portion of the emitted photons are transmitted through the material 110 and are incident on the nanoparticles 120. In response to at least incident photons being above a certain frequency, the nanoparticles 120 emit electrons 140 into the surrounding material 110 and, as a result, may increasing the electron density in the material 110 above the base value. Altering the electron density of the material 110 can, in some implementations, modify electrical and/or optical properties of the material 110 such as the conductivity and/or the refractive index.

In a particular example, the nanoparticles 120 may be gold having a radius of about 10 nm and embedded in a monocrystalline silicon material 110. In this example, the gold nanoparticles 120 may occupy approximately 10% of the material 110 by volume at a depth of about 200 nm. The light source 130 may emit photons having a wavelength of 1.1 μm. Calculations indicate that the electron yield in this implementation may be as high as 0.01 electrons emitted into the material 110 per incident photon. The yield may be reduced or otherwise altered, however, by boundary effects at the silicon/gold interface, or by other effects.

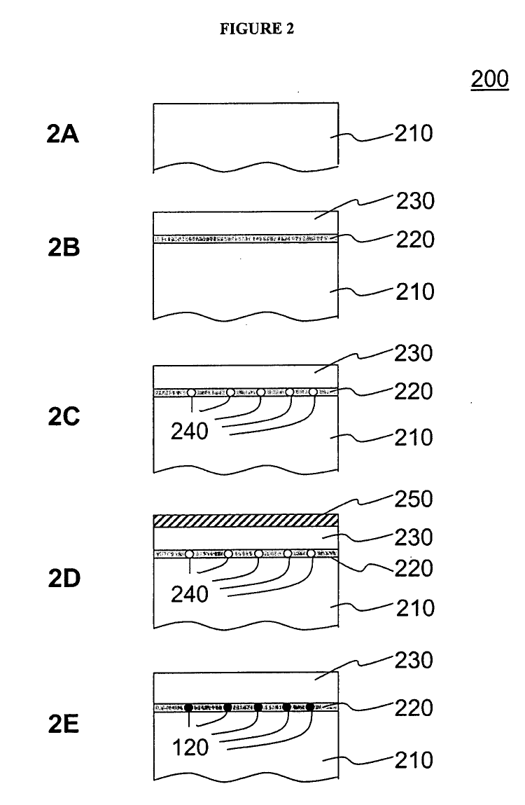

FIG. 2A-E is a series of diagrams illustrating steps of an example process for fabricating nanoparticles 120 embedded in the material 110 of FIG. 1. In particular, the illustrated example process may be used to fabricate self-assembled metal nano-particles in monocrystalline silicon. FIG. 2A illustrates a monocrystalline silicon (Si) substrate 210 which may serve as the beginning structure in the fabrication process. On top of the substrate 210, a monocrystalline, layered heterostructure is grown, for example, using molecular-beam-epitaxial growth. The layered heterostructure includes alternating layers of Si and silicon germanium (Si₁₋ₓGeₓ), where x indicates the percentage (e.g., 0-100%) of Ge in the silicon germanium layers. In an example implementation, the silicon germanium layer is composed of 20% Ge and 80% Si.

FIG. 2B illustrates a single Si₁₋ₓGeₓ layer 220 between the substrate 210 and a single surface Si layer 230. In some implementations, the Si₁₋ₓGeₓ layer 220 may be, for example, 10 nm thick, but the thickness may be more or less than 10 nm in other implementations. The layered heterostructure is then irradiated with electrons or ions to create point defects in the heterostructure. Fluence and energy of the irradiation beam may be chosen to reduce the production of significant damage cascades in the surface Si layer 230. After irradiation, the resulting structure is annealed to allow the formation of self-assembled voids 240 in the Si₁₋ₓGeₓ layer 220. The annealing step may be carried out at a broad range of temperatures (e.g. 100-800° C). Voids 240 in the Si₁₋ₓGeₓ layer 220 are illustrated in FIG. 2C. Next a metal layer 250, such as silver, gold or copper, is deposited on the surface of the Si layer 230, as illustrated in FIG. 2D.

The metal layer 250 may be deposited by low energy ion implantation, physical vapor deposition, laser ablation, magnetic sputtering, electron-beam evaporation, and/or other methods. After metal deposition, the resulting structure is annealed to allow the metal to diffuse into the layered heterostructure and fill the voids in the Si₁₋ₓGeₓ layer 220, thus forming the nanoparticles 120. The annealing step may be carried out at a broad range of temperatures. For example, diffusion occurs at room temperature, but the rate of diffusion may be increased by annealing at a higher temperature (e.g. 100-800° C). Finally, the metal material remaining on the surface after annealing is etched away. The final structure, which includes the nanoparticles 120 embedded in the Si and Si₁₋ₓGeₓ medium after etching is illustrated in FIG. 2E.

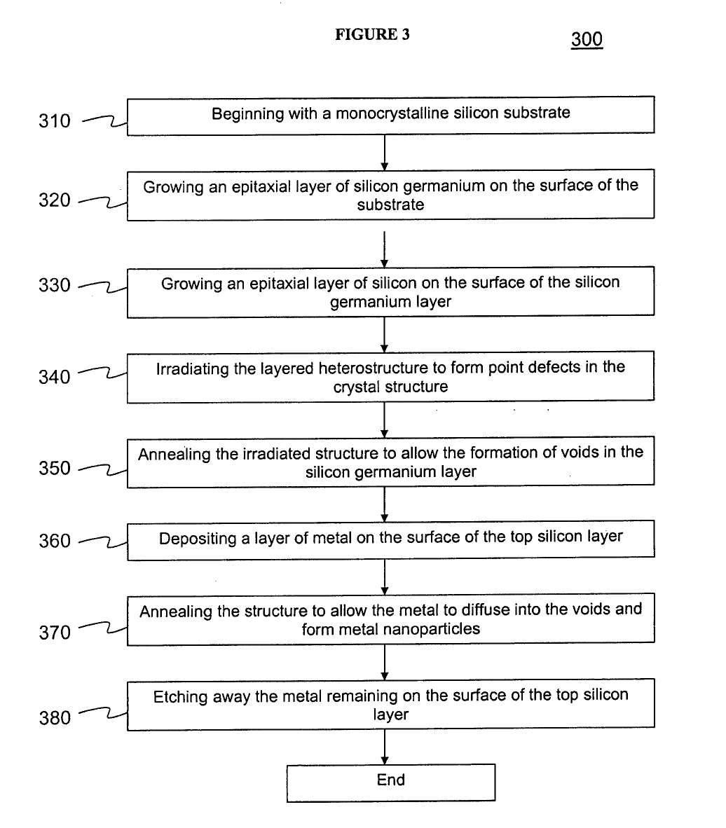

FIG. 3 is a flowchart illustrating an example method 300 for fabricating a device as illustrated in FIG. 2. Generally, the method 300 describes an example technique for fabricating nanoparticles 120 embedded in a material 110 as in system 100 of FIG. 1. In particular, the method 300 describes a technique for fabricating self-assembled metal nano-particles in monocrystalline silicon.

The method 300 begins at step 310 where an epitaxial layer of Si₁₋ₓGeₓ is grown on the surface of a monocrystalline silicon substrate. At step 320, an epitaxial layer of monocrystalline Si is grown above the Si₁₋ₓGeₓ layer. Steps 310 and 320 may be implemented, for example, by molecular beam epitaxial growth. Next in step 330, the layered Si/Si₁₋ₓGeₓ/Si heterostructure is irradiated to form point defects in the Si₁₋ₓGeₓ layer. Irradiation may be done, for example, with electrons or ions. The fluence and the energy of the irradiation beam may be chosen to avoid or otherwise reduce the production of significant damage cascades in the surface Si layer. In step 340, the irradiated sample is annealed so that point defects in the Si₁₋ₓGeₓ layer may migrate and form voids in the Si₁₋ₓGeₓ layer. The voids, for example, may have a diameter of 10 nm. At step 350, the irradiated structure is annealed to allow the formation of voids in the silicon germanium. In step 360, a thin metal layer (e.g., gold, silver or copper) is deposited on the surface of the top Si layer. The metal layer may be deposited by low energy ion implantation, physical vapor deposition, laser ablation, magnetic sputtering, electron-beam evaporation, and/or other methods. In step 370, the structure is annealed to allow diffusion of the metal into the voids of the Si₁₋ₓGeₓ layer, forming metal nano-particles. The annealing step may be carried out, for example, at a temperature of 800° C. Finally in step 380, the metal remaining on the surface of the top silicon layer is etched away.

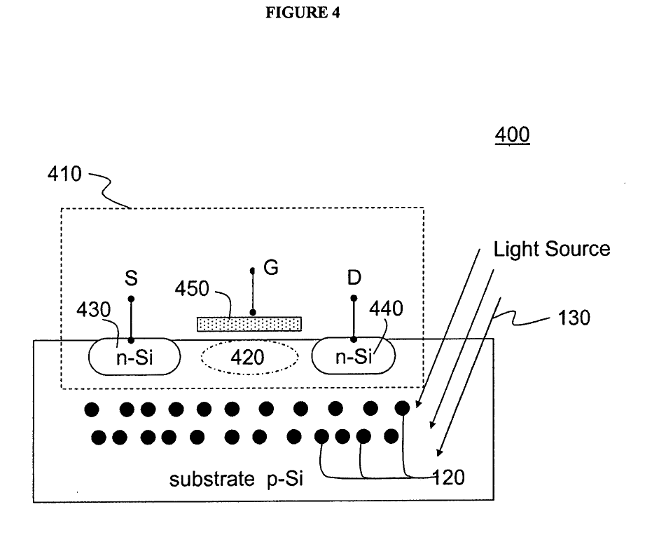

FIG. 4 is a diagram illustrating an example implementation of the system 100 for controlling the electron density in a device in accordance with some implementations of the present disclosure. The example implementation illustrated in FIG. 4 may be used as a switching system 400 for controlling the flow of electrical current. The system 400 includes the light source 130, an NPN transistor 410 including a material 110 that contains embedded nanoparticles 120. In some implementations, when the light source 130 is turned off, the switch is in the “off” state and the channel region 420 of the transistor 410 may not conduct electrons. However, when the light source 130 illuminates the nanoparticles 120, the switch is in the “on” state and the channel region 420 of the transistor 410 may conduct electrical current.

In general, the transistor 410 may be a metal-oxide-semiconductor field effect transistor (MOSFET), a bipolar junction transistor (BJT), a thin film transistor (TFT), or another type of transistor. The illustrated implementation represents an NPN MOSFET configuration. The transistor 410 includes a p-type channel region 420, an n-type source region 430, an n-type drain region 440, an insulating oxide layer 450 and a gate layer 460. The p-type substrate below the transistor 410 forms the material 110 including embedded nanoparticles 120. The conduction properties of the channel region 420 may be modified when photons from the light source 130 impinge on the nanoparticles 120. In this manner, transistor 410 may be selectively switched using the light source 130.

In one aspect of operation, a gate voltage V_{g} is applied between the gate 450 and the substrate 110, and a drain voltage V_{d} is applied between the source 430 and the drain 440. V_{g} is not high enough to directly invert the conduction channel 420 from the p-type to an n-type. Consequently, when the light source 130 is turned off, there may be no significant current flow between the source 430 and the drain 440 through the channel 420. However, when the light source 130 is turned on, photons from the light source 130 may impinge the nanoparticles 120, and electrons may diffuse from the nanoparticles 120 into the p-type substrate material 110. Due to the applied voltage V_{g}, the electrons may be drawn into the channel region 420. In this case, the channel 420 may be inverted from the p-type into and n-type if the electron yield from the nanoparticles 120 is great enough. In some implementations, the channel region 420 becomes conducting, and electrons are transported from the source 430 to the drain 440 via the channel 420. In this way, optical signals may be converted into electrical signals, as the light source 130 acts as a switch for the transistor 410.

In another aspect of operation, the application of the gate voltage V_{g} may not be necessary for controlling the transistor 410. In some implementations, the nanoparticles 120 may be close enough to the channel region 420 that photons emitted from the nanoparticles 120 form an inversion layer in the channel region 420 even when a gate voltage V_{g} does attract the electrons to the channel region 420.

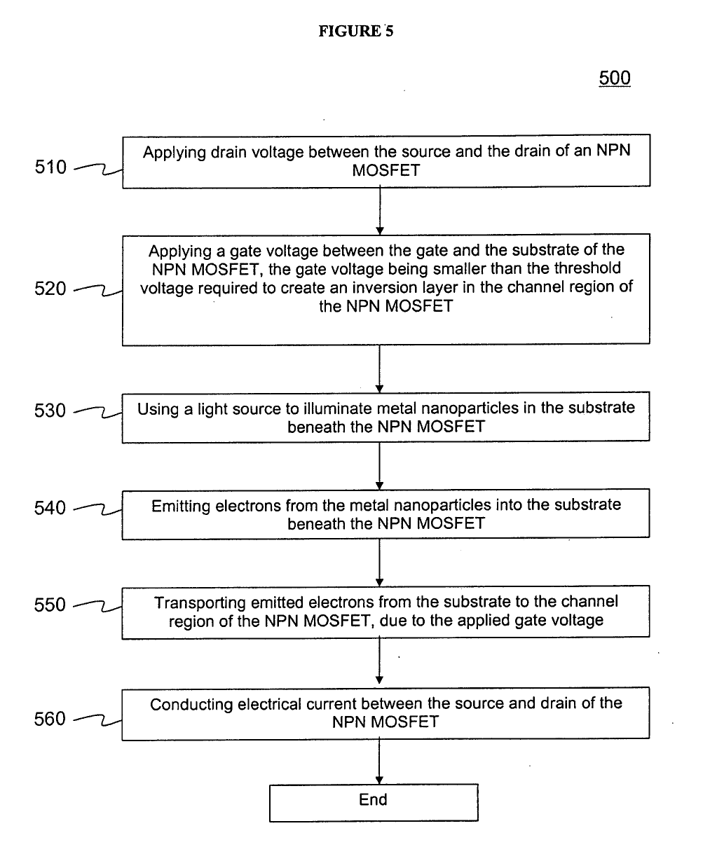

FIG. 5 is a flowchart illustrating an example method 500 for managing the system 400 illustrated in FIG. 4. Generally, the method 500 describes an example technique for converting optical signals into electrical signals. In particular, the method 500 describes a technique for using a light source to induce conduction of electrical current through the channel region between the source and the drain of an NPN MOSFET. The system 400 may use any appropriate combination and arrangement of logical elements implementing some or all of the described functionality.

Method 500 begins at step 510, where a drain voltage is applied between the n-type source and the n-type drain of the MOSFET. Next, at step 520, a gate voltage is applied between the gate and substrate of the MOSFET. The gate voltage is not sufficient to create an inversion layer in the p-type channel region. Therefore, there is no significant flow of electrical current through the p-type channel region between the n-type source and n-type drain. At step 530, a light source is turned on and illuminates metal nano-particles in the p-type substrate beneath the MOSFET. At step 540, electrons are emitted from the nano-particles into the p-type substrate. At step 550, under the due to the applied gate voltage, the electrons are transported from the substrate region to the channel region, forming an inversion layer in the channel region. Finally, in step 560, electrical current is conducted through the channel region between the source and drain.

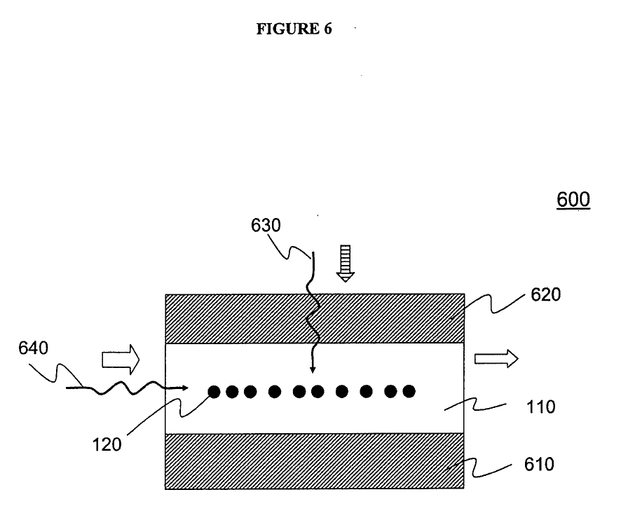

FIG. 6 is a diagram illustrating another example implementation of the system 100 for controlling the electron density in a device in accordance with some implementations of the present disclosure. In the illustrated implementation, the system 600 is a waveguide silicon optical modulator 600. The modulator 600 has a channel and two walls to substantially confine the light in the channel. The channel may be intrinsic Si 110 containing nanoparticles 120. If a light beam 640 is propagating along the channel (e.g., from left to right in FIG. 6), the intensity can, in some implementations, be modulated if another light beam 630 illuminates nanoparticles 120. By illuminating the device 600 with the control light 630 above certain energy, the light-induced electron emission from the nanoparticles 120 may change the refractive index of the channel. In doing so, the light 640 may be modulated.

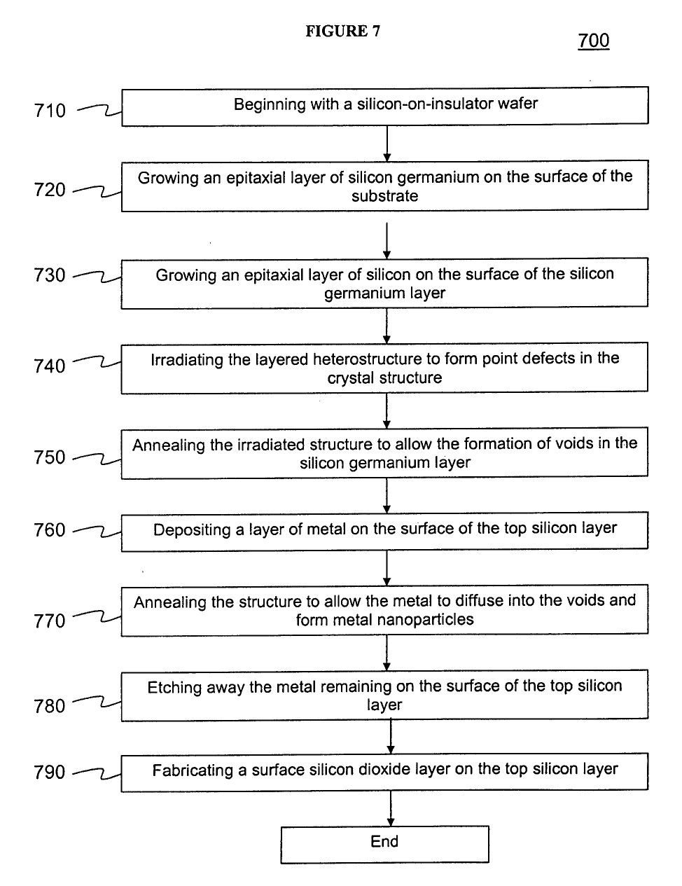

FIG. 7 is a flowchart illustrating an example method 700 for managing the system 600 illustrated in FIG. 6. Generally, the method 700 describes an example technique to fabricate a wave guide modulator. Method 700 begins at step 710, where a silicon-on-insulator (SOI) wafer is used as a substrate. SOI wafer is often a sandwich like structure which contains a buried silicon dioxide between two silicon layers. The top silicon layer is often very thin, with a thickness of around 10 nm to 1 micrometers. At step 720, an epitaxial layer of monocrystalline Si is grown above the Si₁₋ₓGeₓ layer. Next in step 730, the layered Si/Si₁₋ₓGeₓ/Si heterostructure is irradiated to form point defects in the Si₁₋ₓGeₓ layer. Irradiation may be done, for example, with electrons or ions. The fluence and the energy of the irradiation beam may be chosen to avoid or otherwise reduce the production of significant damage cascades in the surface Si layer. In step 740, the irradiated sample is annealed so that point defects in the Si₁₋ₓGeₓ layer may migrate and form voids in the Si₁₋ₓGeₓ layer. The voids, for example, may have a diameter of 10 nm. At step 750, the irradiated structure is annealed to allow the formation of voids in the silicon germanium. In step 760, a thin metal layer (e.g., gold, silver or copper) is deposited on the surface of the top Si layer. The metal layer may be deposited by low energy ion implantation, physical vapor deposition, laser ablation, magnetic sputtering, electron-beam evaporation, and/or other methods. In step 770, the structure is annealed to allow diffusion of the metal into the voids of the Si₁₋ₓGeₓ layer, forming metal nano-particles. The annealing step may be carried out, for example, at a temperature of 800° C. At step 780, the metal remaining on the surface of the top silicon layer is etched away. The method ends with step 790 to fabricate a surface silicon dioxide layer on the top of silicon layer. This can be realized, for example, by either surface oxidation or chemical vapor deposition.

A number of embodiments of the invention have been described. Nevertheless, it will be understood that various modifications may be made without departing from the spirit and scope of the invention.

What is claimed is:

1. A method, comprising:
selectively illuminating at least a portion of a device including material having embedded nanoparticles, wherein the nanoparticles emit electrons in response to light at a certain frequency or above; and
adjusting at least one operating parameter of the device to direct at least a portion of the emitted electrons.

2. The method of claim 1, wherein the device is a transistor.

3. The method of claim 1, wherein the device is an optoelectronic device.

4. The method of claim 1, wherein the at least one operating parameter is a voltage.

5. The method of claim 1, wherein the nanoparticles comprise at least one of gold, silver, or copper.

6. The method of claim 1, wherein the nanoparticles are substantially spherical with a diameter between 1 nm and 10 nm.

7. The method of claim 6, wherein the diameter of the nanoparticles are less than diffusion lengths of emitted electrons.

8. The method of claim 1, the material is a semiconductor.

9. The method of claim 1, wherein the emitted electrons modify one or more properties of the material.

10. The method of claim 9, wherein the one or more properties comprises at least one of conductivity or refractive index.

11. A system, comprising:
a light source configured to selectively illuminate at least a portion of a device including material having embedded nanoparticles, wherein the nanoparticles emit electrons in response to light at a certain frequency or above; and
the device configured to adjust at least one operating parameter of the device to direct at least a portion of the emitted electrons.

12. The system of claim 11, wherein the device is a transistor or an optoelectronic device.

13. The system of claim 11, wherein the at least one operating parameter is a voltage.

14. The system of claim 11, wherein the nanoparticles comprise at least one of gold, silver, or copper.

15. The system of claim 11, wherein the nanoparticles are substantially spherical with a diameter between 1 nm and 10 nm.

16. The system of claim 15, wherein the diameter of the nanoparticles are less than diffusion lengths of emitted electrons.

17. The system of claim 11, the material is a semiconductor.

18. The system of claim 17, wherein the one or more properties comprises at least one of conductivity or refractive index.

19. The system of claim 11, wherein the light source is integrated in the device.

20. A device, comprising:
a material configured to conduct electrons; and
nanocrystals embedded in the material configured to emit electrons in response to at least light having a frequency above a threshold frequency.

21. The device of claim 20, wherein the material comprises a semiconductor.

22. The device of claim 20, wherein the device comprises a transistor or optoelectronic device.

23. The device of claim 20, wherein the nanoparticles are generally spherical with a diameter between 1 nm to 10 nm.
